(19) United States
(12) Patent Application Publication
(10) Pub. No.: US 2017/0190925 A1
(43) Pub. Date: Jul. 6, 2017

(54) Transparent Antistatic Films

(71) Applicant: Enerage Inc., Wujie Township (TW)

(72) Inventors: Mark Y. WU, Wujie Township (TW); Cheng-Yu HSIEH, Wujie Township (TW); Fang-Ru SHEN, Wujie Township (TW); Tsung-Han CHEN, Wujie Township (TW); You-Lin JIAN, Wujie Township (TW)

(21) Appl. No.: 15/077,674

(22) Filed: Mar. 22, 2016

(30) Foreign Application Priority Data
Dec. 31, 2015 (TW) 104144753

(51) Int. Cl. C09D 7/12; H01L 23/60; C09D 133/10; H05K 1/02; C09D 5/00; C09D 127/06

(52) U.S. Cl. CPC C09D 7/1225; C09D 5/00; C09D 127/06; C09D 133/10; H05K 1/0213; H01L 23/60

(57) ABSTRACT

A transparent antistatic film of the present application includes a substrate and a transparent graphene coating, the substrate at least includes a first surface, and the transparent graphene coating is disposed above the first surface of the substrate. The transparent graphene coating has a surface resistance less than 10¹² ohm/sq and a visible transmittance greater than 70% at wavelength of 550 nm, and the transparent graphene coating includes a plurality of surface modified graphene nanosheets and a carrier resin, wherein the plurality of surface modified graphene nanosheets is uniformly dispersed in the carrier resin. With characteristics of the transparent graphene coating, the transparent antistatic film of the present application can prevent various risks of electrostatic breakdown, have a function of electromagnetic wave shielding, and keep original transmittance of the substrate, so that the transparent antistatic film is suitable for use in electronic devices which are sensitive to electrostatic or electromagnetic.

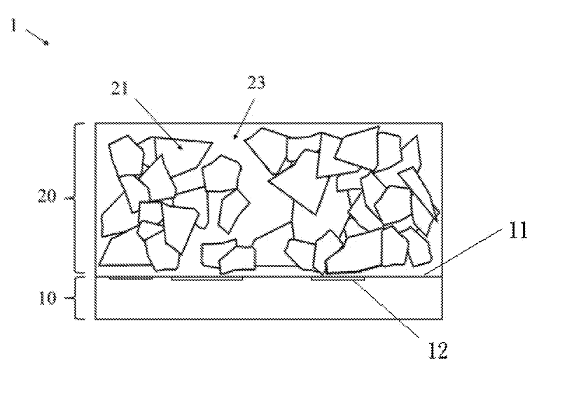

### CROSS-REFERENCE TO RELATED APPLICATION

This application claims the priority of Taiwanese patent application No. 104144753, filed on Dec. 31, 2015, which is incorporated herewith by reference.

### BACKGROUND OF THE INVENTION

1. Field of the Invention

The present application relates to a transparent antistatic film, especially to which uses a transparent graphene coating disposed on a substrate and composed of a plurality of surface modified graphene nanosheets and a carrier resin, so as to improve overall antistatic and electromagnetic wave shielding characteristic, the plurality of surface modified graphene nanosheets can effectively dispersed in the carrier resin, and thus the transparent antistatic film can both have transparent and antistatic characteristics.

2. The Prior Arts

With rapid development of technology and enhancement of electric function, power consumption is significantly increased. In the demand of the electronic devices needing more compact sizes, and power density of electric operation needs to further increase, a resin having antistatic function is thus necessary to protect fine narrow circuits, thereby, failure or damage thereof due to electrostatic breakdown can be obviated, and lifetime of the products can be secured.

On the other hand, shrinkage of circuits of electronic elements also makes extent of interferences between the elements be increasingly significant. In order to obviate such interferences, an electromagnetic wave shielding layer is usually applied to the elements, in terms of optoelectronic display elements, the electromagnetic wave shielding layer further needs to have high light transmittance, to avoid affecting visual perception.

In conventional techniques, conductive powders, such as metal powder, conductive carbon black and the like, have been massively studied to increase conductivity of resin coatings or to reduce resistance thereof, so as to allow the resin coatings have antistatic effect. U.S. Pat. Nos. 3,753,765A and 4,085,087A respectively disclose cases of the antistatic coatings having the conductive carbon black and the metal powder added therein. However, the conductive carbon black is not easy to well combine with the resin, but easy to detach from the composite system to contaminate the substrate or environment. A specific gravity of the metal powder is higher than a specific gravity of the resin that causes phase separation during mixing complex process of the two materials, and thus the composite material has low uniformity. Moreover, in addition to the aforesaid challenge of manufacture art, with the conductive carbon black or the metal powder as conductive filler, transparency of the films tends to significantly reduce, the two demands of transparency and antistatic cannot be taken into account. In case that to manufacture a transparent or half-transparent coating for application is desired, or the coating or application process needs to rely on light transmittance of the resin paste itself, the above two filler materials are obviously confined.

CN Publication No. 103726323A discloses a method of manufacturing an antistatic nano film resin layer, which increases antistatic property of the film by using hygroscopic performance of small molecule inorganic salts. However, properties of such materials would be affected by circumstance conditions, if the environment is at low humidity, such antistatic additives often cannot be effective. In addition to the inorganic salts, some patents also disclose conductive polymers and carbon nanotubes as antistatic fillers/filler materials of transparent conductive coatings. CN Publication No. 102333825A discloses an antistatic coating by using conductive polymers as an additive, and it declares that the coating has 91% light transmittance. CN Publication No. 102388109 A discloses an antistatic coating by using carbon nanotubes as an additive, the coating can be cladded on a polymer substrate, to prevent surface charge accumulation and external scratches. However, the conductive polymer has a problem of lifetime, and durability and performance cannot be taken into account; the carbon nanotubes can overcome the aforesaid problems, but the carbon nanotubes have problems of a very expensive price and hard to disperse, and to massively manufacturing the products have technical difficulties therein. Therefore, there is an urgent need of looking for a cost-effective conductive filler to simultaneously solve the transmittance and electrostatic problems.

Since Andre Geim and Konstantin Novoselov at the University of Manchester in the UK in 2004 successfully manufactured graphene from a piece of graphite by using adhesive tape and were thus awarded the Nobel Prize in Physics for 2010, the graphene has been widely applied to various fields due to its excellent physical properties like electrical conductivity, thermal conductivity, chemical resistance, and so on. Specifically, the graphene is 0.335 nm in thickness, about only one carbon diameter, and constructed by two-dimensional crystal bonded with sp² hybrid orbital in a form of hexagonal honeycomb. It is believed that the graphene is the thinnest material in the world, and its mechanical strength is larger than steel by one hundred times more with its specific gravity only one fourth of steel. In particular, the graphene is also a material with excellent thermal conductivity and electrically conductivity. Its theoretical resistivity reaches to 10⁻⁶ Ω·cm, and the graphene is thus an excellent conductive material.

However, a problem in the actual application of graphene is that the graphene is easy to congregate or stack together to form a bulk. As a result, the graphene is hard to be uniformly dispersed in the medium. Thus, to prevent graphene sheets from stacking on each other so as to obtain graphene powder with high uniformity and less layers is the primary bottleneck for the present industries.

CN Publication No. 103804553A discloses a composite material of graphene/polyvinyl chloride, which mainly utilizes: anchoring an azo initiator on a surface of the graphene by using electrostatic adsorption; then, reacting vinyl chloride monomers with modified graphene, and in-situ polymerizing the polyvinyl chloride, to allow a good interface affinity formed within the graphene and the polyvinyl chloride, so as to achieve composite material properties. However, in the patent, the graphene do not be effectively dispersed in deionized water during the anchoring process, and the azo be directly anchored thereon. Such way results in limited anchoring effect and extent of the azo, it is probable that the problem of lacking of interface affinity within the graphene and the polyvinyl chloride probably is still existed after the in-situ polymerization. Additionally, the preparing method of the patent needs to adjust the graphene aqueous solution into strong alkaline, the derived alkaline aqueous solution is not only unfriendly to the environment, but also requires expensive cost of wastewater treatment. The azo anchored graphene needs to be stored in a dark environment at low temperature, and thus this method is not suitable for use in an industrial mass production.

CN Publication No. 103450537A discloses an antistatic composite containing high molecular weight polyethylene/graphene; the antistatic composite is prepared by pelletizing the graphene and the high density polyethylene with a high speed mixer, and then thermoforming the pelletized graphene and high density polyethylene. A main drawback of the method is that mixing two dry powders of the high density polyethylene and the graphene is performed with the high speed mixer, although the method allows the graphene adhering to or coating on surfaces of the high density polyethylene, and then a three-dimensional conductive network is formed through hot pressing, the two dry powders are hardly to be uniformly mixed in the high speed mixing, due that a particle density difference between one and the other is more than 30 times, and the high density polyethylene particle of tending spherical shape is obviously different from the graphene of two-dimensional sheet. Moreover, the antistatic composite requires a high uniformity on the filler in the antistatic composite; therefore, without adding solvents, an effect of mixing the dry powders of the graphene and the high density polyethylene that is carried out is quite limited.

CN Patent No. 102775700B discloses a method of preparing an antistatic composite of PVC/graphene, which includes steps as follows. Firstly, expanded graphite are mixed with PVC masterbatch; the mixture is rolled and milled by using a pan mill chemical reactor; the composite is then molten and extruded with a screw extruder; and then the molten and extruded composite is pelletized. Although the method can previously prepare the masterbatch that is beneficial to form finished products of various shapes through following plasticization, graphene in the composite is formed by plural repeated rolling and milling, and fresh surfaces of the expanded graphite are continuously exfoliated then formed during the procedure of milling the expanded graphite to form the graphene, at this time, if the unsteady fresh surfaces are lack of protection with effective surfactants, the graphene will reunite with each other, the reunited region probably cannot effectively form an antistatic network after the composite is formed, and even have a risk of affecting mechanical strength of the material.

CN Publication No. 102627003A discloses a method of preparing an antistatic layer, a display device and an electrostatic protective film. The antistatic effect is achieved by adhering a transparent conductive base and a graphene layer in the patent. Although the antistatic layer configuration asserted in this patent can achieve a desired effect, the graphene film manufactured through vapor deposition consumes time and energy, and attaching the graphene layer to the base material further requires an accompanying transfer procedure. Therefore, in considerations of manufacture process and cost, this method is not suitable for industrial production procedure.

In view of these problems, it is urgent to develop a method, which allows graphene uniformly dispersed in the resin, has a simple process that can be effectively produced and easy to achieve the industrialized production, wherein the graphene is simply added and uniformly dispersed in the resin, and interfaces between filler and resin base are effectively enhanced, so that an antistatic coating can have high stabilities of material and antistatic. With a lower percolation threshold provided by excellent electrical properties of the graphene, the aforesaid drawbacks in conventional techniques can thus be solved.

### SUMMARY OF THE INVENTION

A main aspect of the present application is to provide a transparent antistatic film, including a substrate and a transparent graphene coating, wherein the substrate at least includes a first surface and a transparent graphene coating disposed on the first surface of the substrate. The transparent graphene coating has a surface resistance less than 10¹² ohm/sq and a visible transmittance greater than 70% at wavelength of 550 nm, and includes a plurality of surface modified graphene nanosheets and a carrier resin, wherein the plurality of surface modified graphene nanosheets is uniformly dispersed in the carrier resin.

The surface modified graphene nanosheets used in the present application are fewer-layer or multi-layer graphene sheets, and the graphene therein has a purity greater than 95 wt %, a thickness in a range of 1 nm to 20 nm, and a lateral plane dimension in a range of 1 um to 100 um.

The carrier resin in the present application can be polymer resin, which can occur curing polymerization or cross linking reaction by elevating temperature or under UV radiation. Moreover, the carrier resin of the present application can further include a surfactant, an assistant agent for viscosity and processing control, or a combination thereof. The assistant agent includes a diluent, a plasticizer, a cross-linking agent, an adhesive promoter, a filler, a leveling agent, a thixotropic agent, an initiator or a catalyst.

Since the transparent antistatic film provided by the present application has a very excellent antistatic performance, and the static dissipation performance can be enhanced depending on an increased amount of the surface modified graphene nanosheets, the transparent antistatic film can simultaneously have adjustable antistatic and transparent properties. In addition, the transparent antistatic film disclosed in the present application can be manufactures by disposing it on the substrate through a processing method such as screen printing, blade coating, roller coating, spin coating, brush coating, spray coating, and the like, and thus the transparent antistatic film quite has an industrial applicability.

### BRIEF DESCRIPTION OF THE DRAWINGS

FIGURE is a schematic diagram illustrating an embodiment of transparent antistatic film according to the present application.

### DETAILED DESCRIPTION OF THE PREFERRED EMBODIMENT

The embodiments of the present invention accompanying the drawing and element characters will be more thoroughly described as follows, so that those ordinarily skilled in the art after reviewing the specification can implement the present application.

Please refer to FIGURE. The FIGURE is a schematic diagram illustrating an embodiment of the present application. It is noted, for presenting the main features of the present application, that the FIGURE schematically illustrates relative relationship of the main elements therein but not based on actual size; therefore, thicknesses, sizes, shapes, arrangements, and configurations in the FIGURE are presented for reference only, they are not intended to be exhaustive or to be limited to the scope of the present application.

As shown in the FIGURE, a transparent antistatic film 1 of the present application mainly includes a substrate 10 and a transparent graphene coating 20, wherein the substrate 10 at least includes a first surface 11, as an upper surface in the FIGURE, and an electronic circuit 12 can be formed on the first surface 11. The transparent graphene coating 20 is disposed on the first surface 11 of the substrate 10, the transparent graphene coating 20 has a surface resistance less than 10¹² ohm/sq and a visible transmittance greater than 70% at wavelength of 550 nm, and includes a plurality of surface modified graphene nanosheets 21 and a carrier resin 23, wherein the plurality of surface modified graphene nanosheets 21 is uniformly dispersed in the carrier resin 23 to form a web-like electrically conductive structure. Further, a weight percentage of the surface modified graphene nanosheets 21 accounting for the transparent antistatic film 1 is in 0.01-5 wt %.

It is noted, for facilitating explanation of the technical features of the present application, that each the surface modified nano graphene sheet 21 in the FIGURE is shown as a lateral direction of the thin sheet shape; that is, actually from an angle of viewing the FIGURE, a portion of the plurality of the surface modified graphene nanosheets 21 will show their front surfaces, or a portion of the plurality of the graphene nanosheets 21 will simultaneously show partial front surfaces and partial lateral surfaces.

The electronic circuit formed on the first surface 11 of the substrate 10 can be a device of an integrated circuit or a photoelectric display.

In general, the transparent graphene coating 20 of the present application at wavelength of 550 nm has a visible transmittance greater than 60%, for example, 70 to 90%, at wavelength of 550 nm. The transparent graphene coating 20 has a surface resistance less than 10¹³ ohm/sq, preferably less than 10¹² ohm/sq, more preferably the surface resistance in 10⁷ to 10¹¹ ohm/sq.

The plurality of surface modified graphene nanosheets 21 has a bulk density in a range of 0.1 g/cm³ to 0.001 g/cm³, a thickness in a range of 1 nm to 20 nm, a lateral plane dimension in a range of 1 um to 100 um, a ratio of the lateral plane dimension to the thickness in a range of 20 to 10000, and a specific surface area in 15 to 750 m²/g.

Each the surface modified nano graphene sheet 21 has at least a surface modified species of chemical structure represent by formula Mx(R)y(R′)z, wherein M represents a metal element selected from at least one of silicon, titanium, zirconium and aluminum; R represents a hydrophilic functional group; R′ represents a lipophilic functional group; 0≦x≦6, 1≦y≦20, and 1≦z≦20; and the hydrophilic functional group and the lipophilic functional group respectively chemically bond to the plurality of surface modified graphene nanosheets 21 and the carrier resin 23.

Specifically, R is selected from at least one group of alkoxy, carbonyl, carboxyl, acyloxy, amido, alkyleneoxy and alkyleneoxy carboxyl; R′ is selected from at least one group of vinyl, alicyclic oxyalkyl, styryl, methyl propene acyloxy, propene acyloxy, aliphatic amino, chloro propyl, aliphatic thiol, aliphatic sulfide, isocyanato, aliphatic urea group, aliphatic carboxyl, aliphatic hydroxyl, cyclohexyl, phenyl, aliphatic formyl, acetyl and benzoyl.

An oxygen content of the plurality of surface modified graphene nanosheets 21 is in 1-20 wt %.

The carrier resin 23 of the present application can be selected from optically clear resins. Specifically, the carrier resin 23 can be selected from at least one resin of polyacrylate, polyvinyl ether, polyvinylidene fluoride, polyethyleneterephthalate, polyurethane, polyethylene oxide, polyacrylonitrile, polyacrylamide, polymethacrylate, polymethylmethacrylate, polyvinylacetate, polyvinylpyrrolidone, polytetra(ethylene glycol)diacrylate, polyimide, cellulose acetate, cellulose acetate butyrate, cellulose acetate propionate, ethyl cellulose, cyanoethyl cellulose, cyanoethyl polyvinyl alcohol, carboxylmethyl cellulose, polyvinyl chloride, polyolefine and silicone resin. Additionally, the carrier resin 23 also can be selected from thermosetting resins or photo-curable resins.

The carrier resin of the present application can further include at least an assistant agent, for example: an electrically conductive agent, at least a surfactant, a viscosity modifying agent, a coupling agent and a thixotropic agent, for adjusting properties of the transparent conductive graphene coating, such as conductivity, processing, adhesion, and transmittance.

The electrically conductive agent can be selected from at least one of conductive polymers, inorganic salts and organic salts, for assisting the surface modified graphene nanosheets 21 to achieve antistatic effect, and overall material cost can be balanced thereby.

The surfactant can be selected from at least one of saturated fatty acid, unsaturated fatty acid, and polyunsaturated fatty acid, wherein the saturated fatty acid includes at least one of stearic acid, lauric acid, palmitic acid and myristic acid; the unsaturated fatty acid includes at least one of palmitoleic acid and oleic acid; and the polyunsaturated fatty acid includes at least one of linoleic acid and linolenic acid.

The viscosity modifying agent can be selected from at least one of terephthalates, fatty acid esters, phosphate esters, epoxy esters, or polymers of polyesters.

The coupling agent has a chemical structure represent by formula Mx(R)y(R′)z, wherein M represents a metal element comprising at least one of silicon, titanium, zirconium and aluminum; R represents a hydrophilic functional group; R′ represents a lipophilic functional group; 0≦x≦6, 1≦y≦20, and 1≦z≦20; and the hydrophilic functional group and the lipophilic functional group are used for allowing the plurality of surface modified graphene nanosheets 21 and the carrier resin 23 be bonded with chemical bond formed therebetween, so that the coupling agent is used for adjusting a problem of probably insufficient amount of the surface modified species, when the graphene nanosheets has less specific surface area. The coupling agent includes but not limited to silanes, titanates, zirconates, aluminum zirconates, and aluminates.

The thixotropic agent can be selected from at least one of silicon dioxide, bentonite, hydrogenated castor oil, polyamide wax, kaolin, asbestos, chlorinated alkene compound, metallic soap, hydroxyethyl cellulose, polyvinyl alcohol and polyacrylates.

For further presenting the specific effect of the transparent antistatic film of the present application, thereby an ordinary skilled in the art can more clearly understand overall operation, the actual operation of the present application will be thoroughly described in following exemplary embodiments.

The surface modified graphene nanosheets are used in all the following exemplary embodiments, the step of surface modification includes sub steps of functionalizing graphene nanosheets and forming a surface modification species.

The sub step of functionalizing the graphene nanosheets includes: reacting the graphene nanosheets, heated potassium hydroxide, and hydrogen peroxide or sulfuric acid; then forming COOH or OH functional groups on surfaces of the graphene nanosheets, alternatively, modifying the graphene nanosheets with ultraviolet light or ozone to obtain the functionalized graphene nanosheets.

The sub step of forming the surface modification species includes: adding a coupling agent to react with the functionalized graphene nanosheets, so as to form a surface modification species on the functionalized graphene nanosheets. A chemical structure of the coupling agent is represented as Mx(R)y(R′)z, wherein M represents a metal element including at least one of silicon, titanium, zirconium and aluminum; R represents a hydrophilic functional group; R′ represents a lipophilic functional group; 0≦x+6; 1≦y≦20; and 1≦z≦20; and the hydrophilic functional group and the lipophilic functional group allow the plurality of surface modified graphene nanosheets and the carrier resin be bonded with chemical bond formed therebetween. An oxygen content of the surface modified graphene nanosheets is in 1-20 wt %.

Exemplary embodiments 1-4 use the surface modified graphene nanosheets to perform translucent stripping adhesive tests. After the aforesaid surface modified graphene nanosheets are added therein, the stripping adhesive achieves antistatic effect and still maintains translucency.

### Exemplary Embodiment 1

A recipe includes polyvinyl chloride of 60 wt %, epoxy resin of 10 wt %, phenolic resin of 10 wt %, phthalates of 10 wt %, barium stearate of 2 wt %, triphenyl phosphate of 2.5 wt %, calcium carbonate of 2 wt %, silicon dioxide of 2 wt %, the surface modified graphene nanosheets of 1.5 wt %, wherein the polyvinyl chloride, the epoxy resin and the phenolic resin are as the carrier resin; the phthalates are as the viscosity modifying agent; the barium stearate, the triphenyl phosphate and the silicon dioxide are used for increasing effects of cohesive strength and adhesion.

Firstly, the recipe is premixed in accordance with the above ratio, and uniformly mixed for 5 minutes by using a planetary high-speed mixer at a revolution speed of 1600 rpm and a rotation speed of 880 rpm. Then, titanates accounting for 0.5% weight of the carrier resin is added therein as the coupling agent, the recipe added with the coupling agent is uniformly mixed for 3 minutes at a revolution speed of 1600 rpm and a rotation speed of 352 rpm, and a transparent slurry including the graphene nanosheets having the surface modified species can be thus obtained. Then, the transparent slurry including the surface modified graphene nanosheets is coated on a glass substrate through a doctor blade method, a thickness of a transparent graphene coating is about 30 μm; by heating and baking it at 150° C. for 30 minutes in an oven or a hot plate, the transparent graphene coating is thus solidified to form a desired transparent antistatic film.

### Exemplary Embodiment 2

A recipe includes polyvinyl chloride of 60 wt %, epoxy resin of 10 wt %, phenolic resin of 10 wt %, phthalates of 10 wt %, barium stearate of 2 wt %, triphenyl phosphate of 2.5 wt %, calcium carbonate of 2 wt %, silicon dioxide of 2 wt %, the surface modified graphene nanosheets of 1.5 wt %, wherein the polyvinyl chloride, the epoxy resin and the phenolic resin are as the carrier resin; the phthalates are as the viscosity modifying agent; the barium stearate, the triphenyl phosphate and the silicon dioxide are used for increasing effects of cohesive strength and adhesion.

In exemplary embodiment 2, the surface modified graphene nanosheets are previously dispersed in hexane, the hexane containing the surface modified graphene nanosheets is then added in the carrier resin, and the carrier resin added with the surface modified graphene nanosheets is stirred to mix by blades. After the mixing is performed, the hexane is removed by a reduced pressure and concentrated machine. Then, the recipe is uniformly mixed for 5 minutes by using a planetary high-speed mixer at a revolution speed of 1600 rpm and a rotation speed of 880 rpm. Then, titanates accounting for 0.7% weight of the carrier resin is added therein as the coupling agent, the recipe added with the coupling agent is uniformly mixed for 3 minutes at a revolution speed of 1600 rpm and a rotation speed of 352 rpm, and a transparent slurry including the surface modified graphene nanosheets can be thus obtained. Then, the transparent slurry including the surface modified graphene nanosheets is coated on a glass substrate through a screen printing method, a thickness of a transparent graphene coating is about 30 μm; by heating and baking it at 150° C. for 30 minutes in an oven or a hot plate, the transparent graphene coating is thus solidified to form a desired transparent antistatic film.

### Exemplary Embodiment 3

A recipe used in the exemplary embodiment 3 is similar to exemplary embodiment 2, the surface modified graphene nanosheets are previously dispersed in hexane. A difference between exemplary embodiments 2 and 3 is that the hexane is removed followed by adding the graphene nanosheets, which are wetted by the hexane, in the carrier resin, and the recipe is uniformly mixed for 5 minutes by using the planetary high-speed mixer at a revolution speed of 1600 rpm and a rotation speed of 880 rpm. Then, titanates accounting for 0.7% weight of the carrier resin is added therein as the coupling agent, the recipe added with the coupling agent is uniformly mixed for 3 minutes at a revolution speed of 1600 rpm and a rotation speed of 352 rpm, and a transparent slurry including the surface modified graphene nanosheets can be thus obtained. Then, the transparent slurry including the surface modified graphene nanosheets is coated on a glass substrate through a screen printing method, a thickness of a transparent graphene coating is about 30 μm; by heating and baking it at 150° C. for 30 minutes in an oven or a hot plate, the transparent graphene coating is thus solidified to form a desired transparent antistatic film

### Exemplary Embodiment 4

A recipe includes polyvinyl chloride of 65 wt %, epoxy resin of 12 wt %, phenolic resin of 10 wt %, bis(2-ethylhexyl) terephthalate of 11 wt %, the surface modified graphene nanosheets of 2 wt %, wherein the polyvinyl chloride, the epoxy resin and the phenolic resin are as the carrier resin, the bis(2-ethylhexyl) terephthalate is as the viscosity modifying agent.

Firstly, the bis(2-ethylhexyl) terephthalate and the surface modified graphene nanosheets are premixed in accordance with the above ratio, and uniformly mixed for 5 minutes by using the planetary high-speed mixer at a revolution speed of 1600 rpm and a rotation speed of 880 rpm. Then, the polyvinyl chloride of 65 wt %, the epoxy resin of 12 wt % and the phenolic resin of 10 wt % are added therein; then, titanates accounting for 1% weight of the carrier resin is further added therein as the coupling agent, the recipe added with the coupling agent is uniformly mixed for 3 minutes at a revolution speed of 1600 rpm and a rotation speed of 352 rpm, and a transparent slurry including the surface modified graphene nanosheets can be thus obtained. Then, the transparent slurry including the surface modified graphene nanosheets is coated on a glass substrate through a doctor blade method, a thickness of a transparent graphene coating is about 30 μm; by heating and baking it at 150° C. for 30 minutes in an oven or a hot plate, the transparent graphene coating is thus solidified to form a desired transparent antistatic film.

A test result of the above exemplary embodiments is shown as table 1.

TABLE 1

| | Peel | | Transmittance |
|---|---|---|---|
| | electrostatic | Surface | at wavelength |
| | voltage | resistance | of 550 nm |
| | (kV) | (ohm/sq.) | (%) |
| Exemplary embodiment 1 | 0.59 | 8.77 × 10⁹ | 65 |
| Exemplary embodiment 2 | 0.13 | 6.08 × 10⁸ | 60 |
| Exemplary embodiment 3 | 0.03 | 1.28 × 10⁹ | 61 |
| Exemplary embodiment 4 | 0.28 | 4.37 × 10⁸ | 70 |
| Comparative example 1 | 4.20 | >2 × 10¹² | 83 |

In general, a surface resistance of an insulting material, which is easy to accumulate electrostatic, is usually greater than 10¹³ ohm/sq, and a surface resistance required for an antistatic material is preferably in 10⁶ and 10¹¹ ohm/sq. From the experiment results of exemplary embodiments 1, 2, 3, 4 and comparative example 1, it is obvious that the transparent antistatic films of the present application can effectively exclude electrostatic, and all the transparent graphene coatings have good optic transmittance. It is worthy to be mentioned that the transparent graphene coating will not affect chemical and physical properties of current electronic circuits, so that the transparent graphene coating can be directly disposed on a substrate having the electronic circuits formed on a surface thereof, and thus the transparent antistatic film of the present application indeed have very high industrial applicability.

Moreover, the transparent antistatic film of the present application can be also applied to an optical pressure sensitive adhesive. Exemplary embodiments 5 and 6 use the surface modified graphene nanosheets to perform the test examples of the optical pressure sensitive adhesive. After the surface modified graphene nanosheets of the present application are added therein, the optical pressure sensitive adhesive achieves antistatic effect, and still maintains good transparency. Exemplary embodiments are shown as follows.

### Exemplary Embodiment 5

The carrier resin includes polymethylmethacrylate of 40 wt % and ethyl acetate of 60 wt %. Based on a weight of the carrier resin, the surface modified graphene nanosheets of 0.3 wt % and PEDOT:PSS of 1 wt % are added in the carrier resin; then, a transparent slurry including the surface modified graphene nanosheets is coated on a polyethylene terephthalate substrate through a doctor blade method, a thickness of a transparent graphene coating is about 10 μm; by heating and baking it at 100° C. for 30 minutes in an oven or a hot plate, the transparent graphene coating is thus solidified to form a desired transparent antistatic film.

### Exemplary Embodiment 6

The carrier resin includes polymethylmethacrylate of 40 wt % and ethyl acetate of 60 wt %. Based on a weight of the carrier resin, the surface modified graphene nanosheets of 0.05 wt % and sodium alkylsulfonate of 1 wt % are added in the carrier resin, wherein the sodium alkylsulfonate is as the electrically conductive agent. Then, a transparent slurry including the surface modified graphene nanosheets is coated on a polyethylene terephthalate substrate through a doctor blade method, a thickness of a transparent graphene coating is about 10 μm; by heating and baking it at 100° C. for 30 minutes in an oven or a hot plate, the transparent graphene coating is thus solidified to form a desired transparent antistatic film.

TABLE 2

| | | Transmittance |
|---|---|---|
| | Surface | at wavelength |
| | resistance | of 550 nm |
| | (ohm/sq.) | (%) |
| Exemplary embodiment 5 | 1.86 × 10¹¹ | 80 |
| Exemplary embodiment 6 | 2.40 × 10⁹ | 87 |
| Comparative example 2 | >10¹² | 88 |

From the experiment results of exemplary embodiments 5, 6 and comparative example 2, it is obvious that the transparent antistatic films of the present application can effectively exclude electrostatic, and the transparent graphene coatings have visible transmittance at wavelength of 550 nm close to 90%.

In summary, main features of the present application are that the surface modified species of the graphene nanosheets can improve compatibility and affinity of the graphene in the carrier resin, so that the graphene nanosheets can be uniformly dispersed in the carrier resin, and the conventional problems that the graphene even the carbon nanotubes are not easy to disperse can thus be solved. In further tests of the transparent antistatic films of exemplary embodiments 1-6, haze thereof are less than 30% or scraper fineness thereof are less than 15 um, these results sufficiently represent that the surface modified graphene nanosheets are uniformly dispersed in the carrier resin, and the film comply with a requirement of optical level. Therefore, the transparent antistatic film of the present application can effectively suppress electrostatic, so as to prevent electrostatic impact to the substrate, and electromagnetic wave shielding effect can be further achieved, the optical transparency is also maintained; thus, the transparent antistatic film of the present application is very suitable for use in a photoelectric display device or an integrated circuit device, which requires antistatic or electromagnetic wave shielding and needs to maintain transparency appeal.

In addition, the transparent antistatic film of the present application can be formed by mixing the graphene, the resin, the surface modifier and other optional additives, the mixing can performed with the planetary high-speed mixer, a high shear dispersing apparatus, an ultrasonication apparatus or other apparatus capable of uniformly mixing the materials. Therefore, a requirement of manufacturing the transparent antistatic film including the surface modified graphene nanosheets can be met without a special apparatus of additional design, economy of reducing cost is achieved, and competitiveness of products on the market is enhanced.

Although the present invention has been described with reference to the preferred embodiments, it will be well understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A transparent antistatic film, comprising:
a substrate, at least comprising a first surface; and
a transparent graphene coating, disposed on the first surface of the substrate, having a surface resistance less than 10¹² ohm/sq and a visible transmittance greater than 70% at wavelength of 550 nm, and comprising a plurality of surface modified graphene nanosheets and a carrier resin, wherein the plurality of surface modified graphene nanosheets is uniformly dispersed in the carrier resin.

2. The transparent antistatic film according to claim 1, wherein a material of the substrate is glass, plastic or a semiconductor wafer.

3. The transparent antistatic film according to claim 1, wherein the first surface of the substrate further has an electronic circuit formed thereon, and the transparent graphene coating is disposed on the electronic circuit.

4. The transparent antistatic film according to claim 1, wherein a weight percentage of the plurality of surface modified graphene nanosheets accounting for the transparent graphene coating is in 0.01-5 wt %.

5. The transparent antistatic film according to claim 1, wherein the surface resistance of the transparent graphene coating is in 10⁷ to 10¹¹ ohm/sq.

6. The transparent antistatic film according to claim 1, wherein the plurality of surface modified graphene nanosheets uniformly dispersed in the carrier resin represents that haze of transparent graphene coating is less than 30%, or scraper fineness of transparent graphene coating is less than 15 um.

7. The transparent antistatic film according to claim 1, wherein the plurality of surface modified graphene nanosheets has a bulk density in 0.1 g/cm³ to 0.001 g/cm³, a thickness in 1 nm to 20 nm, a lateral plane dimension in 1 um to 100 um, and a specific surface area in 15 to 750 m²/g.

8. The transparent antistatic film according to claim 1, wherein each the nano graphene sheet has at least a surface modified species of chemical structure represent by formula Mx(R)y(R′)z, wherein M represents a metal element comprising at least one of silicon, titanium, zirconium and aluminum; R represents a hydrophilic functional group; R′ represents a lipophilic functional group; 0≦x≦6, 1≦y≦20, and 1≦z≦20; and the hydrophilic functional group and the lipophilic functional group respectively chemically bond to the plurality of surface modified graphene nanosheets and the carrier resin.

9. The transparent antistatic film according to claim 8, wherein R is selected from at least one group of alkoxy, carbonyl, carboxyl, acyloxy, amido, alkyleneoxy and alkyleneoxy carboxyl; R′ is selected from at least one group of vinyl, alicyclic oxyalkyl, styryl, methyl propene acyloxy, propene acyloxy, aliphatic amino, chloro propyl, aliphatic thiol, aliphatic sulfide, isocyanato, aliphatic urea group, aliphatic carboxyl, aliphatic hydroxyl, cyclohexyl, phenyl, aliphatic formyl, acetyl and benzoyl.

10. The transparent antistatic film according to claim 1, wherein an oxygen content of the plurality of surface modified graphene nanosheets is in 1-20 wt %.

11. The transparent antistatic film according to claim 1, wherein the carrier resin is selected from at least one resin of polyvinylidene fluoride, polymethylmethacrylate, polyethyleneterephthalate, polyurethane, polyethylene oxide, polyacrylonitrile, polyacrylamide, polymethacrylate, polymethylmethacrylate, polyvinylacetate, polyvinylpyrrolidone, polytetra(ethylene glycol)diacrylate, polyimide, cellulose acetate, cellulose acetate butyrate, cellulose acetate propionate, ethyl cellulose, cyanoethyl cellulose, cyanoethyl polyvinyl alcohol, carboxylmethyl cellulose, polyvinyl chloride, polyolefine and silicone resin.

12. The transparent antistatic film according to claim 1, wherein the transparent graphene coating further comprises at least one of an electrically conductive agent, a surfactant, a viscosity modifying agent, a coupling agent and a thixotropic agent.

13. The transparent antistatic film according to claim 12, wherein the electrically conductive agent is selected from at least one of conductive polymers, inorganic salts and organic salts.

14. The transparent antistatic film according to claim 12, wherein the surfactant is selected from at least one of saturated fatty acid, unsaturated fatty acid and polyunsaturated fatty acid, wherein the saturated fatty acid comprises at least one of stearic acid, lauric acid, palmitic acid and myristic acid; the unsaturated fatty acid comprises at least one of palmitoleic acid and oleic acid; the polyunsaturated fatty acid comprises at least one of linoleic acid and linolenic acid.

15. The transparent antistatic film according to claim 12, wherein the viscosity modifying agent is selected from at least one of terephthalates, fatty acid esters, phosphate esters, epoxy esters and polyesters.

16. The transparent antistatic film according to claim 12, wherein the coupling agent has a chemical structure represent by formula Mx(R)y(R′)z, wherein M represents a metal element comprising at least one of silicon, titanium, zirconium and aluminum; R represents a hydrophilic functional group; R′ represents a lipophilic functional group; 0≦x≦6, 1≦y≦20, and 1≦z≦20; and the hydrophilic functional group and the lipophilic functional group are used for forming chemical bonding between the plurality of surface modified graphene nanosheets and the carrier resin.

17. The transparent antistatic film according to claim 16, wherein the coupling agent is selected from at least one of silanes, titanates, zirconates, aluminum zirconates and aluminates.

18. The transparent antistatic film according to claim 12, wherein the thixotropic agent is selected from at least one of silicon dioxide, bentonite, hydrogenated castor oil, polyamide wax, kaolin, asbestos, chlorinated alkene compound, metallic soap, hydroxyethyl cellulose, polyvinyl alcohol and polyacrylates.
